(19) United States
(12) Patent Application Publication
(10) Pub. No.: US 2026/0246471 A1
(43) Pub. Date: Aug. 20, 2026

(54) PHASE ROTATOR NON-LINEARITY DETECTION SYSTEM, METHOD AND DEVICE

(71) Applicant: Marvell Asia Pte Ltd, Singapore (SG)

(72) Inventors: Manisha Gambhir, Cupertino, CA (US); Shyam Sundar Sivakumar, Cupertino, CA (US); Ahmed Mostafa, San Jose, CA (US)

(21) Appl. No.: 19/540,281

(22) Filed: Feb. 13, 2026

Related U.S. Application Data
(60) Provisional application No. 63/758,990, filed on Feb. 14, 2025.

(51) Int. Cl. H03L 7/087

(52) U.S. Cl. CPC H03L 7/087

(57) ABSTRACT

A phase interpolation system including a clock source, a phase rotator, a non-linearity detector and a non-linearity corrector. The phase rotator receives outputs phase rotated clock signals derived from a clock signal and a different phase state. The non-linearity detector compares a phase of each of the rotated clock signals to a phase of a reference clock signal and outputs a signal indicating a phase difference between the clock signal and each of the rotated clock signals. The non-linearity corrector determines an extent to which the phase difference changes non-linearly as different phase states are selected by the phase rotator and provides a control signal based on which the phase rotator corrects the exhibited non-linearity.

### RELATED APPLICATIONS

This application claims priority under 35 U.S.C. § 119(e) of the co-pending U.S. provisional patent application Ser. No. 63/758,990 filed Feb. 14, 2025, and titled “Analog Based Foreground Detection of Phase Rotator (Phase Interpolator) Non-linearity,” which is hereby incorporated by reference.

### FIELD OF INVENTION

The present invention relates to phase rotator systems, methods and devices. More particularly, the present invention relates to phase rotator non-linearity detection systems, methods and devices.

### BACKGROUND OF THE INVENTION

High performance phase interpolator (PI) based clock data recovery (CDR) is needed for high bandwidth density (high Tb/mm) serdes links. PI-based CDR enables highly area-efficient clock recovery loops for high lane count applications. Alternatives, are per lane digital controlled oscillator (DCO) based CDR, but that suffers from poor area efficiency. However, PI-based CDR suffers from integral non-linearity (INL) which severely limit bit error rate (BER) in the presence of tracking frequency offset between incoming data and local receiver measured in parts per million (ppm). For example, PI-based CDR with an uncorrected INL is able to have greater than two orders of BER degradation at 200ppm offset. Thus, there is a need to be able to precisely measure and/or compensate for INL in PI-based CDR circuits.

However, this measurement needs to be able to measure tiny phase errors at extreme accuracy. For example, for a least significant bit of 8-bit PI on 28 G clock=140 fs. Thus, there would be a need to measure fractions of LSB (sub-100 fs) accurately such that a simple time to digital clock (TDC) will not work. Further, there are practical issues to detection once the link is in mission mode. Specifically, one cannot isolate phase rotator (PR) INL from other system impairments once full CDR loop is running. Moreover, PR INL is not part of link training or adaptation such that one cannot detect and correct apriori.

### BRIEF SUMMARY OF THE INVENTION

A phase interpolation system including a clock source, a phase rotator, a non-linearity detector and a non-linearity corrector. The phase rotator receives outputs phase rotated clock signals derived from a clock signal and a different selectable phase. The non-linearity detector compares a phase of each of the rotated clock signals to a phase of a reference clock signal and outputs a signal indicating a phase difference between the clock signal and each of the rotated clock signals. The non-linearity corrector determines an extent to which the phase difference changes non-linearly as different phases are selected by the phase rotator and provides a control signal to the phase rotator that corrects the exhibited non-linearity.

A first aspect is directed to a phase interpolation system. The system comprises a clock source that produces a clock signal, a phase rotator that receives the clock signal and outputs a plurality of phase rotated clock signals that are each derived from the clock signal and a different phase state of a plurality of supported phase states of the phase rotator, a non-linearity detector that compares a phase of each of the rotated clock signals to a phase of a reference clock signal and outputs a plurality of pulses that each indicate a phase difference between the clock signal and a different one of the rotated clock signals, wherein each one of the plurality of supported phase states is paired with the phase difference that was determined based on the rotated clock signal derived from the one of the plurality of supported phase states and a non-linearity corrector that determines an extent to which the pairs of the phase differences and the supported phase states have a non-linear relationship with each other, and generates one or more control signals based on the extent, wherein operation of the phase rotator is adjusted based on the control signals such that the extent of the non-linear relationship is reduced.

In some embodiments, the reference clock signal has a same frequency as the clock signal. In some embodiments, the reference clock signal has a phase whose relationship to a phase of the clock signal is fixed. In some embodiments, the plurality of phase rotated clock signals include a separate phase rotated clock signal for each of the plurality of supported phase states that the phase rotator is configured to support. In some embodiments, the system further comprises one or more frequency dividers that lower the frequency of the clock signal and the plurality of phase rotated clock signals by a factor N before the non-linearity detector receives the clock signal and the plurality of phase rotated clock signals. In some embodiments, the system further comprises an analog to digital converter that receives the pulses from the non-linearity detector and converts the pulses to a digital output signal that is received by the non-linearity corrector. In some embodiments, the non-linearity detector comprises a phase detector circuit coupled with a low-pass filter circuit. In some embodiments, the non-linearity detector comprises a DC gain circuit that receives and amplifies an output of the low-pass filter circuit. In some embodiments, the clock source is a phase locked loop circuit.

Another aspect is directed to a phase interpolation circuit. The circuit comprises a phase rotator that receives a clock signal and outputs a plurality of phase rotated clock signals that are each derived from the clock signal and a different phase state of a plurality of supported phase states of the phase rotator and a non-linearity detector that compares a phase of each of the rotated clock signals to a phase of a reference clock signal and outputs a plurality of pulses that each indicate a phase difference between the clock signal and a different one of the rotated clock signals, wherein each one of the plurality of supported phase states is paired with the phase difference that was determined based on the rotated clock signal derived from the one of the plurality of supported phase states.

In some embodiments, the reference clock signal has a same frequency as the clock signal. In some embodiments, the reference clock signal has a phase whose relationship to a phase of the clock signal is fixed. In some embodiments, the plurality of phase rotated clock signals include a separate phase rotated clock signal for each of the plurality of supported phase states that the phase rotator is configured to support. In some embodiments, the circuit further comprises one or more frequency dividers that lower the frequency of the clock signal and the plurality of phase rotated clock signals by a factor N before the non-linearity detector receives the clock signal and the plurality of phase rotated clock signals. In some embodiments, the circuit further comprises an analog to digital converter that receives the pulses from the non-linearity detector and converts the pulses to a digital output signal. In some embodiments, the non-linearity detector comprises a phase detector circuit coupled with a low-pass filter circuit. In some embodiments, the non-linearity detector comprises a DC gain circuit that receives and amplifies an output of the low-pass filter circuit.

Another aspect is directed to a method of operating a phase interpolation system. The method comprises providing a clock signal with a clock source, with a phase rotator, receiving the clock signal and outputting a plurality of phase rotated clock signals that are each derived from the clock signal and a different phase state of a plurality of supported phase states of the phase rotator, with a non-linearity detector, comparing a phase of each of the rotated clock signals to a phase of a reference clock signal and outputting a plurality of pulses that each indicate a phase difference between the clock signal and a different one of the rotated clock signals, wherein each one of the plurality of supported phase states is paired with the phase difference that was determined based on the rotated clock signal derived from the one of the plurality of supported phase states and with a non-linearity corrector, determining an extent to which the pairs of the phase differences and the selectable phases have a non-linear relationship with each other, and generating one or more control signals based on the extent, wherein operation of the phase rotator is adjusted based on the control signals such that the extent of the non-linear relationship is reduced.

In some embodiments, the reference clock signal has a same frequency as the clock signal. In some embodiments, the reference clock signal has a phase whose relationship to a phase of the clock signal is fixed. In some embodiments, the plurality of phase rotated clock signals include a separate phase rotated clock signal for each of the plurality of supported phase states that the phase rotator is configured to support. In some embodiments, the method further comprises, with one or more frequency dividers, lowering a frequency of the clock signal and the plurality of phase rotated clock signals by a factor N before the non-linearity detector receives the clock signal and the plurality of phase rotated clock signals. In some embodiments, the method further comprises, with an analog to digital converter, receiving the pulses from the non-linearity detector and converting the pulses to a digital output signal that is received by the non-linearity corrector. In some embodiments, the non-linearity detector comprises a phase detector circuit coupled with a low-pass filter circuit. In some embodiments, the non-linearity detector comprises a DC gain circuit, further comprising receiving and amplifying an output of the low-pass filter circuit. In some embodiments, the clock source is a phase locked loop circuit.

Another aspect is directed to a phase interpolation system. The system comprises means for generating a clock that produces a clock signal, means for rotating phase that receives the clock signal and outputs a plurality of phase rotated clock signals that are each derived from the clock signal and a different phase state of a plurality of supported phase states of the phase rotator, means for detecting a non-linearity that compares a phase of each of the rotated clock signals to a phase of a reference clock signal and outputs a plurality of pulses that each indicate a phase difference between the clock signal and a different one of the rotated clock signals, wherein each one of the plurality of supported phase states is paired with the phase difference that was determined based on the rotated clock signal derived from the one of the plurality of supported phase states and means for correcting a non-linearity that determines an extent to which the pairs of the phase differences and the selectable phases have a non-linear relationship with each other, and generates one or more control signals based on the extent, wherein operation of the means for rotating phase is adjusted based on the control signals such that the extent of the non-linear relationship is reduced

### BRIEF DESCRIPTION OF THE DRAWINGS

FIG. 1 illustrates a phase interpolation system according to some embodiments.

FIG. 2 illustrates a block diagram of an exemplary phase rotator according to some embodiments.

FIG. 3 illustrates a block diagram of an exemplary phase detector according to some embodiments.

FIG. 4 illustrates circuit diagram of an exemplary low pass filter according to some embodiments.

FIG. 5 illustrates a signal diagram of an exemplary reference signal, phase rotated signals and output pulse signals as received/generated by the non-linearity detector according to some embodiments.

FIG. 6 illustrates a graph of phase difference/pulse width/voltage verses phase rotator phase state according to some embodiments.

FIG. 7 illustrates a method of operating a phase interpolation system 100 according to some embodiments.

### DETAILED DESCRIPTION OF THE INVENTION

In the following description, numerous details are set forth for purposes of explanation. However, one of ordinary skill in the art will realize that the invention can be practiced without the use of these specific details. Thus, the present invention is not intended to be limited to the embodiments shown but is to be accorded with the widest scope consistent with the principles and features described herein.

Embodiments are directed to a phase interpolation system including a clock source, a phase rotator, a non-linearity detector and a non-linearity corrector. The phase rotator receives outputs phase rotated clock signals derived from a clock signal and a different selectable phase. The non-linearity detector compares a phase of each of the rotated clock signals to a phase of a reference clock signal and outputs a signal indicating a phase difference between the clock signal and each of the rotated clock signals. The non-linearity corrector determines an extent to which the phase difference changes non-linearly as different phases are selected by the phase rotator and provides feedback to the phase rotator that corrects the exhibited non-linearity.

As a result, the phase interpolation system, method and device has the benefit of providing high performance with a small footprint. It enables a compact and complete solution to phase rotator non-linearity without overdesign for mismatch (e.g. lower power). It handles both systematic and random errors (resulting in higher yield). It measures clock path in isolation and high speed signal path error is turned into low speed/DC error. Further, the phase interpolation system, method and device has the benefit of being easy to implement with simple circuits (e.g. XOR phase detector at lower speeds, low pass filter, DC amplifier etc.). Additionally, it enables high resolution (sub-100 fs), high linearity measurement, it is scheme immune to offsets and all measurements are relative to first point. Moreover, the phase interpolation system, method and device implements a scheme that does not need precise conversion gain wherein the INL is a relative measure and realized low frequency/DC gain needs to be high enough to cover the dynamic range of the measurement ADC.

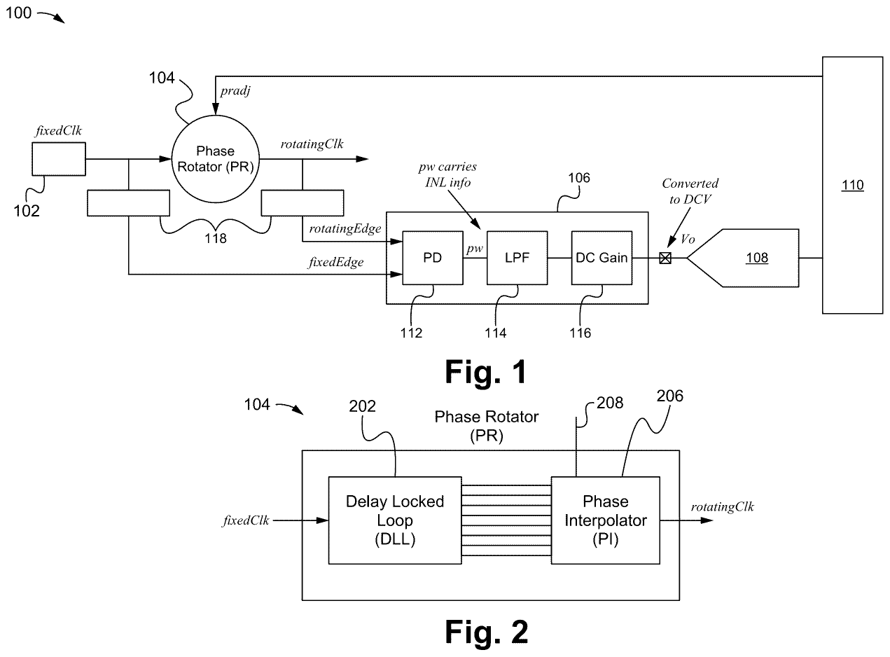

FIG. 1 illustrates a phase interpolation system 100 according to some embodiments. As shown in FIG. 1, the system 100 comprises a clock source 102, a phase rotator 104, a non-linearity detector (NLD) 106, a digitizer circuit 108, a non-linearity correction component 110 and one or more frequency dividers 118. Alternatively, the frequency dividers 118 and/or the digitizer circuit 108 are able to be omitted. The clock source 102 is coupled to the input of phase rotator 104 and provides an input clock signal (e.g. fixedClk) to the phase rotator 104. Additionally, as shown in FIG. 1, the clock source 102 is able to be coupled with the NLD 106 in order to provide a reference clock signal (e.g. fixed edge clock) to the NLD 106. Indeed, in such embodiments the input clock signal and the reference clock signal are able to be the same signal (except with the reference clock signal having its frequency divided by a fixed factor N when the frequency divider 118 is included in the system 100).

Alternatively, instead of using the input clock signal as the reference clock signal, a second clock source (not shown) is able to provide the reference clock signal as long as this reference clock signal provided by the second clock source has the same frequency as the input clock signal (before any frequency dividing) and has a phase whose relationship with the phase of the input clock signal is fixed/unchanging). Again, this reference clock signal provided by the second clock source is able to have its frequency divided by a fixed factor N when the frequency divider 118 is included in the system 100. In some embodiments, the clock source 102 (and/or second clock source) is able to be a phase locked loop circuit. Alternatively, the clock source 102 (and/or second clock source) is able to comprise other types of clock generating circuits.

The phase rotator 104 is coupled with the NLD 106 and provides a set of phase-rotated signals (or signals having a rotating edge) to the NLD 106. In some embodiments, where a frequency divider 118 is included in the system, the set of phase-rotated signals are able to have their frequency divided by a fixed factor N (where N is the same factor used in the other divider 118 to divide the reference signal). FIG. 2 illustrates a block diagram of an exemplary phase rotator 104 according to some embodiments. As shown in FIG. 2, the phase rotator 104 comprises a delay locked loop (DLL) 202 coupled with a phase interpolator 206. The DLL 202 receives the clock signal from the clock source 102 and produces a plurality of signals that are coupled to the phase interpolator 206. The phase interpolator 206 receives the signals and produces the set of phase rotated/shifted clock signals based on one or more control signals/messages 208 (e.g. one or more digital control words/PI-codes) received from a controller (not shown). In some embodiments, the controller is a part of the non-linearity correction component 110. Alternatively, the controller is able to be a separate component. It should be noted that often the terms “phase rotator” and “phase interpolator” are used interchangeably in the art. As used herein, “phase rotator” is able to refer to any component or collection of components that are configured to input a signal and output a set of phase shifted/rotated versions of that signal. As used herein, “phase interpolator” is able to refer to any component or collection of components that are configured to input two or more signals and output one or more signals having a phase in between the phases of any two of the input signals (e.g. phases not equal to the phases of the input signals, but rather interpolated between those phases). Thus, the “phase rotator” is able to include a “phase interpolator” as well as one or more other components that help facilitate its function of rotation/shifting the phase of the input signals.

The NLD 106 is able to comprise a phase detector 112, a low pass filter 114 and an amplifier circuit 116. The phase detector 112 is able to provide a pulse signal (e.g. PW) whose pulses correspond to a difference in phase of a currently input phase rotated signal and the reference signal. The low pass filter 114 is able to filter the pulse signal and the amplifier circuit 116 is able to amplify the voltage of the filtered pulse signal. In some embodiments, the amplifier circuit 116 is a DC gain circuit (e.g. 4× to 8× DC signal gain). Alternatively, the amplifier circuit 116 is able to be other types of amplifiers known in the art and/or is able to be omitted.

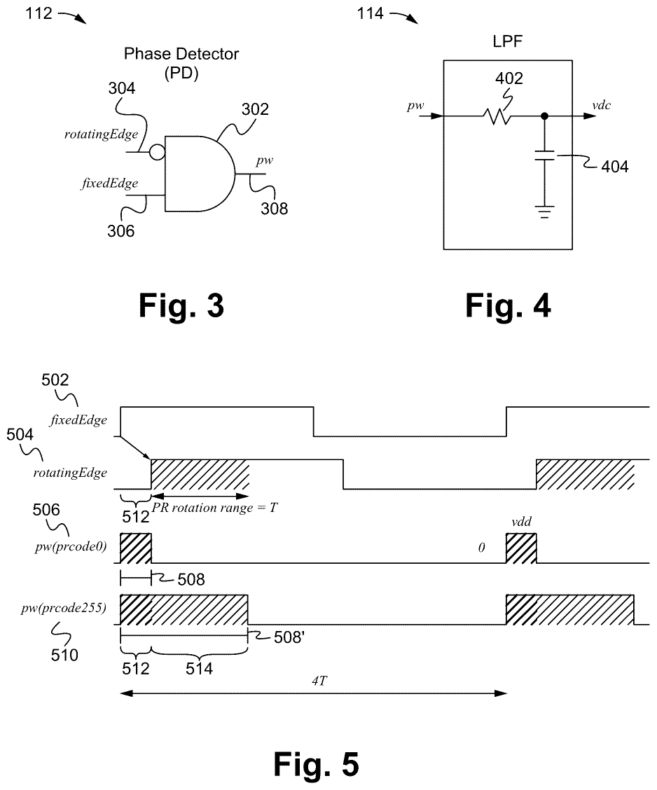

FIG. 3 illustrates a block diagram of an exemplary phase detector 112 according to some embodiments. As shown in FIG. 3, the phase detector 112 comprises an AND gate 302 having an inverted first input 304, a second input 306 and an output 308. The inverted first input 302 is coupled with the phase rotator 104 (e.g. directly or via a divider 118) to receive the set of phase rotated signals (e.g. rotating edges) and the second input is coupled with the clock source 102 (or second clock source) (e.g. directly or via a divider 118) to receive the reference clock (e.g. fixed edges). The pairs of signals are logically ANDed together with the resulting pulse signal output via the output 308. Specifically, the output 308 is coupled with the low pass filter 114 for providing the pulse signal (e.g. PW) based on the phase difference between the inversion of the phase rotated signals and the reference clock. Alternatively, the inverted first input 302 and the second input 302 are able to be reversed (e.g. such that the reference clock signal is inverted and the rotated clock signals are not). FIG. 4 illustrates circuit diagram of an exemplary low pass filter 114 according to some embodiments. As shown in FIG. 4, the low pass filter 114 comprises a resistor 402 (for receiving the pulse signal from the phase detector PD) coupled with a capacitor 404 which together filter out unwanted noise. Alternatively, other circuits known in the art are able to be used to implement phase rotator 104, phase detector 112 and/or the low pass filter 114.

The digitizer circuit 108 is coupled between the NLD 106 and the non-linearity correction component 110 for receiving the output pulse signal (e.g. as filtered and/or amplified) and convert the signal to a digital signal. In some embodiments, the digitizer circuit 108 is an analog to digital converter (ADC) (e.g. sigma-delta ADC). Alternatively, the digitizer circuit 108 is able to be other types of ADCs known in the art. The non-linearity correction component 110 is coupled between the digitizer circuit 108 and the phase rotator 104. The non-linearity correction component 110 receives the converted pulse signal, detects any non-linearity in the converted pulse signal, and generates one or more control signals/messages that cause the phase rotator 104 to adjust operation (e.g. delay/time/phase adjustment) to correct the detected non-linearity. In some embodiments, the non-linearity correction component 110 is implemented via firmware. Alternatively, non-linearity correction component 110 is able to comprises one or a combination of hardware, software and/or firmware. In some embodiments, the non-linearity correction component 110 transmits the control signals/messages to the controller of the phase rotator 104, which then adjusts the control signals/messages sent to the phase rotator 104 to effectuate the correction (e.g. wherein the correction is embedded within the DLL and/or PI controls). Alternatively, the controller of the phase rotator 104 is able to be a part of the non-linearity correction component 110 and/or the non-linearity correction component 110 is able to transmit the control signals/messages to the phase rotator 104 directly to effectuate the correction.

In operation, the clock source 102 generates and transmits the clock signal to the phase rotator 104. The phase rotator 104 receives the clock signal, and for each of a number of phase states supported by the phase rotator 104, the phase rotator 104 outputs a phase rotated signal (e.g. rotating edge) based on the selected phase state (e.g. as determined by a received control word/PI code corresponding to that phase state) and the input clock signal. For example, for an initial phase state (e.g. phase 0 or phase interpolator code 0), the rotated signal is able to be the clock signal with a first size phase shift, for a subsequent phase state, the rotated signal is able to be the clock signal with a second size phase shift, and so on. In some embodiments, the phase rotator 104 generates and outputs a phase rotated signal for each of the number of supported phase states (e.g. phases 0-360 or phase interpolator codes 0-255 (for an 8-bit phase interpolator)). Alternatively, the phase rotator 104 only generates and outputs a phase rotated signal for a subset of the number of supported phase states (e.g. three or more phase states). In some embodiments, the phase states included in the subset are equally spaced from the closest other phase states among the supported phase states. Alternatively, one or more of the phase states included in the subset are unequally spaced from the closest other phase states among the supported phase states. In some embodiments, the phase states included in the set are pre-determined and/or pre-programmed. Alternatively, the phase states included in the set are able to be dynamically adjusted (e.g. via the controller of the phase rotator 104).

In any case, the phase rotator 104 transmits the phase rotated signals to an input the phase detector 112 of the NLD 106. In some embodiments, a frequency of the phase rotated signals is divided by a divider 118 before they are received by the NLD 106. In some embodiments, the clock source 102 further transmits the clock signal to another input of the phase detector 112 of the NLD 106 as a reference clock signal. Alternatively, a second clock source is able to generate and transmit the reference clock signal to the input of the phase detector 112. In embodiments where the frequency of the phase rotated signals are divided by a divider 118 before they are received by the NLD 106, the frequency of the reference clock signal (regardless of its source) is also divided by a divider 118 (by the same dividing factor N) before it is received by the NLD 106.

For each of the phase rotated signals, the phase detector 112 receives the phase rotated signal and the reference signal and generates an output pulse signal whose pulse width corresponds to a difference in phase between the two signals. In other words, the phase detector 112 is able to measure rising edge to rising edge phase/time difference between the rotated and reference signal and generate pulses that change (ideally linearly) as the phase rotator 104 selects each subsequent phase state of the set of phases (where an average value of the pulse voltage is passed to the digitizer circuit 108). For example as shown in FIG. 5, the reference signal 502 is compared to a first phase rotated signal 504 having a minimum or 0 phase shift by the phase rotator 104, and the phase detector 112 produces a pulse signal 506 having a pulse width 508 that corresponds to the difference in phase between the signals. Specifically, in the case where the clock signal used as the reference signal, the phase difference/pulse width 508 would be equal to the phase shift introduced into the phase rotated signal 504 by the phase rotator 104 (e.g. 0), plus the path delay 512 caused by the processing of the clock signal into the phase rotated signal by the phase rotator 104, plus any other delay.

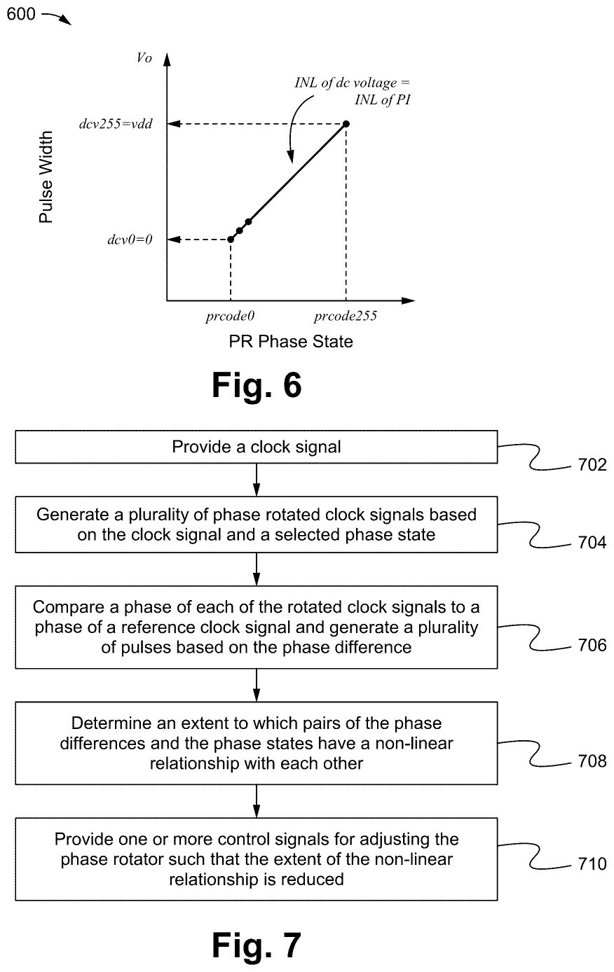

This phase shift difference/pulse width 508 increases for other larger phase shifts introduced into other phase rotated signals, with a largest phase shift difference/pulse width 508′ resulting from the phase rotated signal 510 having the largest introduced phase shift 514 plus the path delay 512 plus any other delay. Accordingly, as shown in the graph 600 of FIG. 6, each output pulse signal 506, 510 has a pulse width 508 that corresponds to the phase shift introduced by the phase rotator 104 (which is based on the selected phase state), plus any other (e.g. non-linear) delay. In particular, the other delay described above will cause the (pulse width/phase difference, phase state) points of the graph 600 to deviate from a linear slope and instead exhibit non-linearities in the relationship of the points with respect to each other that need to be corrected by the non-linearity correction component 110.

The low pass filter 114 receives the output pulse signals, filters unwanted noise, and outputs a filtered pulse signal for each output pulse signal. These filtered pulse signals are then able to be amplified by the amplifier circuit 116 (e.g. increasing its DC gain). Alternatively, the signal amplification/amplifier circuit 116 are able to be omitted. In either case, the filtered pulse signals are received by the converter 108 which converts each of the filtered pulse signals to a corresponding digital signal (whose voltage corresponds to the phase difference between the phase rotated signal and the reference signal upon which the filtered pulse signal was based). The non-linearity correction component 110 receives each of the digital signals, and for each digital signal, associates the signal with phase state (or phase interpolator code) used by the phase rotator 104 to generate the phase rotated signal from which the digital signal was produced. As a result, as shown in FIG. 6, the non-linearity correction component 110 determines a collection of voltage/phase state points that, if there is no error/non-idealities found in the phase rotator 104 (causing other/non-linear delay), each align with a linear slope line.

Accordingly, the non-linearity correction component 110 is able to determine the extent to which any of these points exhibit non-linearity by measuring how much they deviate in voltage from the expected linear value predicted by the slope line. Once the amount of non-linearity is determined for each point, the non-linearity correction component 110 is able to generate a correction signals (and/or adjust existing control signals or cause them to be adjusted) that are transmitted to the phase rotator 104 and cause the phase rotator 104 to compensate for the detected non-linearity of each point. For example, if the non-linearity indicated that for a particular phase state/phase interpolator code, too much phase shift was introduced, the correction signals are able to cause the phase rotator 104 to reduce the phase shift for that state to counteract the non-linearity. Similarly, if the non-linearity indicated that for a particular phase state/phase interpolator code, not enough phase shift was introduced, the correction signals are able to cause the phase rotator 104 to increase the phase shift for that state to counteract the non-linearity. As a result, the phase rotator 104 is able to be accurately tuned such that non-linearities are minimized or eliminated.

FIG. 7 illustrates a method of operating a phase interpolation system 100 according to some embodiments. As shown in FIG. 7, a clock source 102 provides a clock signal at the step 702. A phase rotator 104 receives the clock signal and outputs a plurality of phase rotated clock signals at the step 704. The rotated clock signals are each derived from the clock signal and a different phase/phase state/interpolation state of a plurality of selectable phases/phase states/interpolation states that are supported by the phase rotator 104. For example, if the phase rotator 104 has an 8-bit phase interpolator, it is able to support 256 interpolation states. In some embodiments, the phase state is determined based on a control word/message/signal from the controller of the phase rotator 104. The NLD 106 compares a phase of each of the rotated clock signals to a phase of a reference clock signal and outputs a plurality of pulses at the step 706. Each of the pulses indicate a phase difference between the clock signal and a different one of the rotated clock signals. In particular, a width of the pulses is able to correspond to a phase difference detected between the rotated clock signal and the reference signal. In some embodiments, the reference signal is the clock signal from the clock source 102. Alternatively, the reference signal is able to be a different signal from the clock source 102 or another clock source. The non-linearity correction component 110 determines an extent to which pairs of the phase differences and the phase rotator 104 phases/phase states/interpolator states (that correspond to that phase difference) have a non-linear relationship with each other at the step 708. The non-linearity correction component 110 provides one or more control signals/control words to the phase rotator 104 (or the controller of the phase rotator 104) based on which the operation of the phase rotator 104 is adjusted such that the extent of the non-linear relationship is reduced at the step 710. Thus, the method provides the benefit of correcting detected non-linearities in each phase state of the phase rotator 104.

In some embodiments, the reference clock signal has a same frequency as the clock signal. In some embodiments, the reference clock signal has a phase whose relationship to a phase of the clock signal is fixed. In some embodiments, the method further comprises, with one or more frequency dividers 118, lowering a frequency of the clock signal and the plurality of phase rotated clock signals by a factor N before the non-linearity detector 106 receives the clock signal and the plurality of phase rotated clock signals. In some embodiments, the method further comprises, with an analog to digital converter 108, receiving the pulses from the non-linearity detector 106 and converting the pulses to a digital output signal that is received by the non-linearity correction component 110. In some embodiments, the method further comprises receiving and amplifying an output of the low-pass filter circuit 114 with the amplifier 116.

The phase interpolation system, method and device described herein provides numerous advantages. Specifically, the phase interpolation system, method and device has the benefit of providing high performance with a small footprint. It enables a compact and complete solution to phase rotator non-linearity without overdesign for mismatch (e.g. lower power). It handles both systematic and random errors (resulting in higher yield). It measures clock path in isolation and high speed signal path error is turned into low speed/DC error. Further, the phase interpolation system, method and device has the benefit of being easy to implement with simple circuits (e.g. XOR phase detector at lower speeds, low pass filter, DC amplifier etc.). Additionally, it enables high resolution (sub-100 fs), high linearity measurement, it is scheme immune to offsets and all measurements are relative to first point. Moreover, the phase interpolation system, method and device implements a scheme that does not need precise conversion gain wherein the INL is a relative measure and gain just needs to be high enough to get required dynamic range.

While the system, method and device has been described with reference to numerous specific details, one of ordinary skill in the art will recognize that the invention can be embodied in other specific forms without departing from the spirit of the invention. Thus, one of ordinary skill in the art will understand that the invention is not to be limited by the foregoing illustrative details. For example, although a single non-linearity correction component 110 is described as performing multiple functions, it is understood that the functions are able to be divided amongst a plurality of separate components. Further, it should be noted that although not described in detail for the sake of brevity, the system 100 is able to include or be a part of one or more of an integrated circuit, a software defined network, a top of rack switch, a network interface, additional memory, additional processors, I/O device(s), buses and/or a storage device. The additional memory and/or the memory described herein is able to be any conventional computer memory known in the art such as, but not limited to, a hard drive, DRAM, RAM, SRAM, CDROM, CDRW, DVD, DVDRW, flash memory card or any other storage device. An example of a network interface includes a network card connected to an Ethernet or other type of LAN. The I/O device(s) are able to include one or more of the following: keyboard, mouse, monitor, display, printer, modem, touchscreen, button interface and other devices. In some embodiments, the shared library is able to be a driver for one or more of the I/O devices. The operating system(s), graphical user interface(s), application(s), module(s) and/or other software on the system 100 (and components thereof) are able to be stored in the memory and/or additional memory and/or storage device and processed as applications are typically processed via the processors and/or additional processors of the system 100. The processes are able to be implemented via hardware, software, firmware and/or a combination of two or more of hardware, software and firmware such as memory, software/firmware and/or processors to execute the software/firmware stored on the memory in order to perform the functions of the processes.

We claim:

1. A phase interpolation system, the system comprising:
a clock source that produces a clock signal;
a phase rotator that receives the clock signal and outputs a plurality of phase rotated clock signals that are each derived from the clock signal and a different phase state of a plurality of supported phase states of the phase rotator;
a non-linearity detector that compares a phase of each of the rotated clock signals to a phase of a reference clock signal and outputs a plurality of pulses that each indicate a phase difference between the clock signal and a different one of the rotated clock signals, wherein each one of the plurality of supported phase states is paired with the phase difference that was determined based on the rotated clock signal derived from the one of the plurality of supported phase states; and
a non-linearity corrector that determines an extent to which the pairs of the phase differences and the supported phase states have a non-linear relationship with each other, and generates one or more control signals based on the extent, wherein operation of the phase rotator is adjusted based on the control signals such that the extent of the non-linear relationship is reduced.

2. The system of claim 1, wherein the reference clock signal has a same frequency as the clock signal.

3. The system of claim 2, wherein the reference clock signal has a phase whose relationship to a phase of the clock signal is fixed.

4. The system of claim 1, wherein the plurality of phase rotated clock signals include a separate phase rotated clock signal for each of the plurality of supported phase states that the phase rotator is configured to support.

5. The system of claim 1, further comprising one or more frequency dividers that lower the frequency of the clock signal and the plurality of phase rotated clock signals by a factor N before the non-linearity detector receives the clock signal and the plurality of phase rotated clock signals.

6. The system of claim 1, further comprising an analog to digital converter that receives the pulses from the non-linearity detector and converts the pulses to a digital output signal that is received by the non-linearity corrector.

7. The system of claim 1, wherein the non-linearity detector comprises a phase detector circuit coupled with a low-pass filter circuit.

8. The system of claim 7, wherein the non-linearity detector comprises a DC gain circuit that receives and amplifies an output of the low-pass filter circuit.

9. The system of claim 1, wherein the clock source is a phase locked loop circuit.

10. A phase interpolation circuit, the circuit comprising:
a phase rotator that receives a clock signal and outputs a plurality of phase rotated clock signals that are each derived from the clock signal and a different phase state of a plurality of supported phase states of the phase rotator; and
a non-linearity detector that compares a phase of each of the rotated clock signals to a phase of a reference clock signal and outputs a plurality of pulses that each indicate a phase difference between the clock signal and a different one of the rotated clock signals, wherein each one of the plurality of supported phase states is paired with the phase difference that was determined based on the rotated clock signal derived from the one of the plurality of supported phase states.

11. The circuit of claim 10, wherein the reference clock signal has a same frequency as the clock signal.

12. The circuit of claim 11, wherein the reference clock signal has a phase whose relationship to a phase of the clock signal is fixed.

13. The circuit of claim 10, wherein the plurality of phase rotated clock signals include a separate phase rotated clock signal for each of the plurality of supported phase states that the phase rotator is configured to support.

14. The circuit of claim 10, further comprising one or more frequency dividers that lower the frequency of the clock signal and the plurality of phase rotated clock signals by a factor N before the non-linearity detector receives the clock signal and the plurality of phase rotated clock signals.

15. The circuit of claim 10, further comprising an analog to digital converter that receives the pulses from the non-linearity detector and converts the pulses to a digital output signal.

16. The circuit of claim 10, wherein the non-linearity detector comprises a phase detector circuit coupled with a low-pass filter circuit.

17. The circuit of claim 16, wherein the non-linearity detector comprises a DC gain circuit that receives and amplifies an output of the low-pass filter circuit.

18. A method of operating a phase interpolation system, the method comprising:
providing a clock signal with a clock source;
with a phase rotator, receiving the clock signal and outputting a plurality of phase rotated clock signals that are each derived from the clock signal and a different phase state of a plurality of supported phase states of the phase rotator;
with a non-linearity detector, comparing a phase of each of the rotated clock signals to a phase of a reference clock signal and outputting a plurality of pulses that each indicate a phase difference between the clock signal and a different one of the rotated clock signals, wherein each one of the plurality of supported phase states is paired with the phase difference that was determined based on the rotated clock signal derived from the one of the plurality of supported phase states; and
with a non-linearity corrector, determining an extent to which the pairs of the phase differences and the selectable phases have a non-linear relationship with each other, and generating one or more control signals based on the extent, wherein operation of the phase rotator is adjusted based on the control signals such that the extent of the non-linear relationship is reduced.

19. The method of claim 18, wherein the reference clock signal has a same frequency as the clock signal.

20. The method of claim 19, wherein the reference clock signal has a phase whose relationship to a phase of the clock signal is fixed.

21. The method of claim 18, wherein the plurality of phase rotated clock signals include a separate phase rotated clock signal for each of the plurality of supported phase states that the phase rotator is configured to support.

22. The method of claim 18, further comprising, with one or more frequency dividers, lowering a frequency of the clock signal and the plurality of phase rotated clock signals by a factor N before the non-linearity detector receives the clock signal and the plurality of phase rotated clock signals.

23. The method of claim 18, further comprising, with an analog to digital converter, receiving the pulses from the non-linearity detector and converting the pulses to a digital output signal that is received by the non-linearity corrector.

24. The method of claim 18, wherein the non-linearity detector comprises a phase detector circuit coupled with a low-pass filter circuit.

25. The method of claim 24, wherein the non-linearity detector comprises a DC gain circuit, further comprising receiving and amplifying an output of the low-pass filter circuit.

26. The method of claim 18, wherein the clock source is a phase locked loop circuit.

27. A phase interpolation system, the system comprising:
means for generating a clock that produces a clock signal;
means for rotating phase that receives the clock signal and outputs a plurality of phase rotated clock signals that are each derived from the clock signal and a different phase state of a plurality of supported phase states of the phase rotator;
means for detecting a non-linearity that compares a phase of each of the rotated clock signals to a phase of a reference clock signal and outputs a plurality of pulses that each indicate a phase difference between the clock signal and a different one of the rotated clock signals, wherein each one of the plurality of supported phase states is paired with the phase difference that was determined based on the rotated clock signal derived from the one of the plurality of supported phase states; and
means for correcting a non-linearity that determines an extent to which the pairs of the phase differences and the selectable phases have a non-linear relationship with each other, and generates one or more control signals based on the extent, wherein operation of the means for rotating phase is adjusted based on the control signals such that the extent of the non-linear relationship is reduced.
